(19) United States
(12) Patent Application Publication
(10) Pub. No.: US 2024/0321625 A1
(43) Pub. Date: Sep. 26, 2024

(54) ADSORPTION MEMBER AND METHOD FOR PRODUCING SAME

(71) Applicant: KYOCERA Corporation, Kyoto-shi, Kyoto (JP)

(72) Inventor: Masahiro HARADA, Omihachiman-shi, Shiga (JP)

(21) Appl. No.: 18/577,928

(22) PCT Filed: Jul. 11, 2022
(86) PCT No.: PCT/JP2022/027283

§ 371 Date: Jan. 9, 2024

(30) Foreign Application Priority Data
Jul. 12, 2021 (JP) 2021-115196

(51) Int. Cl. H01L 21/687; H01L 21/683

(52) U.S. Cl. CPC H01L 21/68785; H01L 21/6833; H01L 21/6838; H01L 21/6875; H01L 21/68757

(57) ABSTRACT

An adsorption member of the present disclosure includes a substrate made of ceramic containing silicon carbide as a main component; and a plurality of protrusions formed on a surface of the substrate. Each of the plurality of protrusions includes a placement portion having a placement surface for placing a to-be-treated object and a support portion supporting the placement portion. The placement portion includes a film containing at least one type selected from the group consisting of silicon carbide, diamond-like carbon, amorphous silicon, molybdenum, chromium, and tantalum as a main component. The films are independent of one another for each of the plurality of protrusions.

### TECHNICAL FIELD

The present disclosure relates to an adsorption member such as a vacuum chuck and an electrostatic chuck that hold a to-be-treated object such as a semiconductor wafer, and a method for producing the same.

### BACKGROUND OF INVENTION

A known to-be-treated object such as a semiconductor wafer is held on an adsorption member such as a vacuum chuck or an electrostatic chuck in a production apparatus or an inspection apparatus. When the to-be-treated object is placed on a placement surface of the adsorption member, particles generated by friction between the back surface of the to-be-treated object and the placement surface of the adsorption member may adhere to the to-be-treated object, or particles entering scratches, pores, or the like existing on the placement surface of the adsorption member may sporadically re-adhere to the to-be-treated object due to disturbance such as vibration.

In order to solve such a problem, Patent Document 1 proposes a stage in which an yttria (Y₂O₃) film is formed on a placement surface of a to-be-treated object. Patent Document 1 describes that this yttria (Y₂O₃) film has many protrusions made of Y₂O₃.

### CITATION LIST

### Patent Literature

Patent Document 1: JP 2015-23168 A

### SUMMARY

An adsorption member of the present disclosure includes a substrate made of ceramic containing silicon carbide as a main component; and a plurality of protrusions formed on a surface of the substrate. Each of the plurality of protrusions includes a placement portion having a placement surface for placing a to-be-treated object and a support portion supporting the placement portion. The placement portion includes a film containing at least one type selected from the group consisting of silicon carbide, diamond-like carbon (hereinafter, DLC), amorphous silicon, molybdenum, chromium, and tantalum as a main component. A plurality of the films are independent of one another for each of the plurality of protrusions.

A method for producing the adsorption member of the present disclosure includes processes performed in the following order.
(1) forming, on a surface of a substrate made of ceramic containing silicon carbide as a main component, a recessed portion and a protruding portion that is a remaining portion of the recessed portion,
(2) covering the recessed portion and the protruding portion with a film containing at least one type selected from the group consisting of silicon carbide, DLC, amorphous silicon, molybdenum, chromium, and tantalum as a main component,
(3) splitting the film by applying the film with grinding and/or polishing until an upper surface of the protruding portion is exposed, and
(4) obtaining an adsorption member including the substrate and the protrusion by removing the protruding portion.

The present disclosure provides a processing apparatus and an inspection apparatus including the adsorption member.

### BRIEF DESCRIPTION OF THE DRAWINGS

FIG. 1 is a partially broken perspective view schematically illustrating an embodiment of an adsorption member of the present disclosure.

FIG. 2 is an enlarged cross-sectional view of a part A of FIG. 1.

FIG. 3A is a cross-sectional view illustrating another example of a protrusion in the present disclosure.

FIG. 3B is a cross-sectional view illustrating another example of the protrusion in the present disclosure.

FIG. 4A is a cross-sectional view illustrating still another example of the protrusion in the present disclosure.

FIG. 4B is a cross-sectional view illustrating still another example of the protrusion in the present disclosure.

FIGS. 5A to 5E are process explanatory views illustrating a method for producing the adsorption member of the present disclosure.

### DESCRIPTION OF EMBODIMENTS

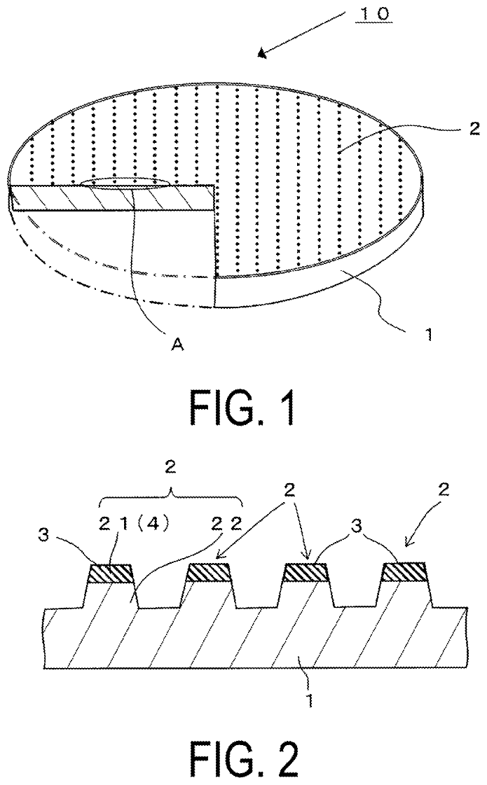

Hereinafter, an adsorption member according to an embodiment of the present disclosure will be described. FIG. 1 schematically illustrates an adsorption member 10 of the present embodiment.

In the adsorption member 10, a plurality of protrusions 2 are formed on an upper surface (surface) of a substrate 1 having a disk shape. FIG. 2 is an enlarged cross-sectional view of the part A in FIG. 1. The protrusion 2 has a frustum shape such as a truncated cone shape or a triangular frustum shape and includes a placement portion 21 having a placement surface 3 for placing a to-be-treated object (not illustrated) and a support portion 22 supporting the placement portion 21. The protrusion 2 is not limited to have a frustum shape and may have a columnar shape, a conical shape, a triangular pyramid shape, or the like. In particular, the protrusion 2 preferably has a frustum shape, and in the case of this shape, it becomes easy to quickly release heat toward the substrate 1 even when the temperature of the to-be-treated object rises.

The substrate 1 is a main body of the adsorption member 10 and is required to have a characteristic that a placed to-be-treated object is not deformed. Therefore, the substrate 1 preferably has high rigidity, high hardness, and high strength. Examples of the material of the substrate 1 include ceramic containing silicon carbide as a main component. Namely, it is a silicon carbide sintered body containing silicon carbide as a main component (over 50 mass %). Such a silicon carbide sintered body has high thermal conductivity and excellent heat dissipation, and thus the temperature change of the to-be-treated object is small. Since the silicon carbide sintered body has electrical conductivity (semiconductivity), it has advantages including less chance of static electricity generation and less chance of electrostatic adhesion of particles. In particular, the content of silicon carbide is preferably equal to or greater than 80 mass % out of the total 100 mass % of the components constituting the ceramic. The other components constituting the ceramic includes, for example, boron carbide.

The components constituting the ceramic may be identified by an X-ray diffractometer (XRD) using a CuKα beam. For the content of each component, after the component is identified, a content of an element constituting the component is determined using an X-ray fluorescence analyzer (XRF) or an ICP emission spectrophotometer and is converted into the identified component.

The protrusion 2 is formed on the surface of the substrate 1 and adsorbs and supports the to-be-treated object. In order not to bring the to-be-treated object into contact with the substrate 1, the to-be-treated object is supported by the plurality of protrusions 2. Since the to-be-treated object is adsorbed and supported by the protrusions 2, the number of particles caught between the to-be-treated object and the placement surface 3 is reduced as compared with the case where the to-be-treated object is directly adsorbed and supported on the substrate 1, and the flatness of the to-be-treated object is less likely to deteriorate.

The support portion 22 constituting the protrusion 2 is ceramic having the same main component as the substrate 1 and is a frustum-shaped protrusion integrally formed and provided on the upper surface of the substrate 1. The placement portion 21 is formed on the upper surface of the support portion 22.

The placement portion 21 is provided to hinder particles entering scratches or fine unevenness existing on the surface of the substrate 1, particles adhering to the surface of the support portion 2, and the like from floating due to an external force such as vibration and adhering to the to-be-treated object. Therefore, the placement portion 21 is required to have a compact surface and little unevenness.

The placement portion 21 includes a film 4 that can form a smooth surface, for example, and is required to be capable of forming a film without causing peeling or cracking of the film 4. In particular, if the difference in thermal expansion coefficient between the support portion 22 and the placement portion 21 is large, peeling or cracking occurs in the placement portion 21 during film formation, and good film formation cannot be performed. Therefore, it is important to reduce the difference in thermal expansion coefficient between the support portion 22 and the placement portion 21. The placement surface 3 preferably has fewer open pores, and for example, the area occupancy of the open pores in the placement surface 3 is preferably 0.5% or less, and in particular equal to or less than 0.2%.

The area occupancy of the open pores is determined by, first, selecting a part where the size and distribution of open pores are observed averagely, and obtaining an observed image in which a range where, for example, the area becomes 3.84×10⁻² mm² (lateral length is 0.226 mm, and longitudinal length is 0.170 mm) is photographed at a magnification of 500 times with a scanning electron microscope. Then, by analyzing this observed image by a method called particle analysis using image analysis software “A Zou Kun (ver. 2.52)” (trade name, manufactured by Asahi Kasei Engineering Corporation. Note that, in the following description, the description of image analysis software “A Zou Kun” refers to the image analysis software manufactured by Asahi Kasei Engineering Corporation), the mean value of the equivalent circle diameters of the open pores can be determined.

As setting conditions of the particle analysis, for example, a threshold value that is an index indicating brightness/darkness of an image is set to 83, a brightness is set to dark, a small figure removal area is set to 0.2 μm², and a noise removal filter is present. Note that in the above-described measurement, the threshold value is set to 83, but the threshold value is adjusted according to the brightness of the observed image. The brightness is set to dark, the binarization method is set to manual, the small figure removal area is set to 0.2 μm², and the noise removal filter is present. Then, the threshold value is manually adjusted so that the marker whose size changes according to the threshold value in the observed image matches the shape of the open pore.

The placement portion 21 is made of the film 4 containing at least one type selected from the group consisting of silicon carbide, diamond-like carbon, amorphous silicon, molybdenum, chromium, and tantalum as a main component. The placement portion 21 including the film 4 has a small difference in thermal expansion coefficient from the support portion 22, and when the to-be-treated object is adsorbed, heat dissipation is facilitated because the thermal conductivity of these main components is high.

Since a film having almost no open pores is obtained, particles hardly adhere to the placement surface 3. Furthermore, static electricity charged on the placement surface 3 can be released, and adhesion of particles can be reduced. When the film 4 contains silicon carbide, diamond-like carbon, or amorphous silicon as a main component, since these main components have high rigidity, deformation of the film 4 is reduced. On the other hand, when the film 4 contains molybdenum, chromium, or tantalum as a main component, these main components have low rigidity, and thus the film 4 easily follows microscopic behavior in the planar direction of the body to be adsorbed.

The film 4 containing these metals as main components includes a film made of a molybdenum alloy, a chromium alloy, or a tantalum alloy.

The main component of the film 4 refers to a component accounting for equal to or greater than 90 mass % out of the total 100 mass % of the components constituting the film 4. The components constituting the film 4 may be identified using a thin film X-ray diffractometer, and the content of each component is determined by a Rietveld method.

When the film 4 contains silicon as a main component, the crystal structure is examined using a thin film X-ray diffractometer. If the half-value width of the peak of silicon appearing around the diffraction angle (2θ) of 28° is equal to or greater than 1.0°, the crystal structure of silicon is amorphous.

When the film 4 contains diamond-like carbon as a main component, it may be identified using a Raman spectrometer. In this case, the ratio I_{D}/IG of the peak intensity of a D band I_{D} to the peak intensity IG of a G band in a Raman optical spectrum obtained by the Raman spectrometer is, for example, equal to or greater than 0.7 and equal to or less than 1.3.

The films 4 are independent of one another for each protrusion 2. Being independent of one another means that the film 4 is split for each protrusion 2. Due to this, as compared with a case where the film 4 covers the entire surface of the substrate 1 and the entire outer peripheral surface of the protrusion 2, the residual strain of the film 4 is reduced, and the flatness of the placement surface 3 is hardly impaired due to thermal deformation or the like. The film 4 may extend toward the outer peripheral surface of the support portion 22 and cover at least a part of the outer peripheral surface of the support portion 22. In this case, particle shedding from the outer peripheral surface of the support portion 22 is reduced, and floating of particles and adhering of the particles to the body to be adsorbed can be reduced.

The thickness of the film 4 is equal to or greater than 30 μm and equal to or less than 400 μm. Since the specific heat capacity of the film 4 is small, the flatness of the placement surface 3, which is the top of the plurality of protrusions 2, is not impaired. In particular, the thickness of the film 4 is equal to or greater than 50 μm and equal to or less than 200 μm.

The surface of the substrate 1 is larger than the placement surface 3 in a mean value of cutting level differences (Rδc) each representing a difference between a cutting level at a load length rate of 25% in a roughness curve and a cutting level at a load length rate of 75% in the roughness curve. Due to this, even if the to-be-treated object is adsorbed to the adsorption member installed in a plasma treatment apparatus and a reaction product generated by the plasma treatment floats, the possibility that this reaction product adheres to the surface of the substrate 1 and floats again is reduced. Since the placement surface 3 has less unevenness, the back surface of the to-be-treated object is less likely to be scratched. Specifically, the difference between the mean values of the cutting level differences (Rδc) between the surface of the substrate 1 and the placement surface 3 is preferably equal to or greater than 0.38 μm.

Here, the mean value of the cutting level differences (Rδc) of the surface of the substrate 1 is equal to or less than 1.4 μm. This makes it difficult for a large particle to shed from the surface of the substrate 1, and the possibility that this particle adheres to the to-be-treated object is reduced.

The cutting level difference (Rδc) is a difference in height direction between cutting levels C (Rrm1) and C (Rrm2) respectively matching load length rates Rmr1 and Rmr2 in the roughness curve defined in JIS B0601:2001. When the cutting level difference (Rδc) is large, unevenness of the measurement target surface becomes large, and when the cutting level difference (Rδc) is small, unevenness of the surface becomes small.

The cutting level difference (Rδc) can be measured using a laser microscope (Ultra-depth color 3D shape measuring microscope (VK-X1000 or its successor model) manufactured by Keyence Corporation) in accordance with JIS B0601:2001. Measurement conditions are as follows: an illumination method is coaxial epi-illumination, a magnification is 480 times, no cutoff value λs, a cutoff value λc is 0.08 mm, no cutoff value λf, with correction of a termination effect, and a measurement range per position from the measurement target surface is 710 μm×533 μm. When the surface of the substrate 1 is a measurement target surface, a measurement target circumferences are drawn around the support portion 22, and the length of each of the circumferences is set to, for example, 1360 μm. When the placement surface 3 is a measurement target surface, a measurement target circumferences are drawn in the vicinity of the outer edge of the placement surface 3, and the length of each of the circumferences is set to, for example, 240 μm. The mean value is calculated from the measured values with the number of measurements equal to or greater than 8.

The surface of the substrate 1 has a larger mean value of a root mean square slope (RΔq) in the roughness curve than that of the placement surface 3. Due to this, even if the to-be-treated object is adsorbed to the adsorption member installed in a plasma treatment apparatus and a reaction product generated by the plasma treatment floats, the possibility that this reaction product adheres to the surface of the substrate 1 and floats again is reduced. Since the placement surface 3 has less unevenness, the back surface of the to-be-treated object is less likely to be scratched.

Specifically, the difference between the mean values of the root mean square slopes (RΔq) between the surface of the substrate 1 and the placement surface 3 is preferably equal to or greater than 0.34.

Here, the mean value of the root mean square slopes (RΔq) of the surface of the substrate 1 is equal to or less than 1.1. This makes it difficult for a large particle to shed from the surface, and the possibility that this particle adheres to the to-be-treated object is reduced.

The root mean square slope (RΔq) in the roughness curve is a root mean square of a local slope dZ/dx at a reference length 1 of the roughness curve, which is measured in accordance with JIS B0601:2001 and is defined by the following formula.

$$R Δ q = \sqrt{\frac{1}{ℓ} {\int }_{0}^{ℓ} {( \frac{d}{dx} Z ( x ) )}^{2} dx} \qquad [ Math . 1 ]$$

The higher the numerical value of the root mean square slope (RΔq), the steeper the unevenness of the surface, and the lower the numerical value of the root mean square slope (RΔq), the smoother the unevenness of the surface.

The root mean square slope (RΔq) can be measured using a laser microscope (VK-X1100 or its successor model manufactured by Keyence Corporation) in accordance with JIS B0601:2001. The measurement conditions and the calculation of the mean value are as described above.

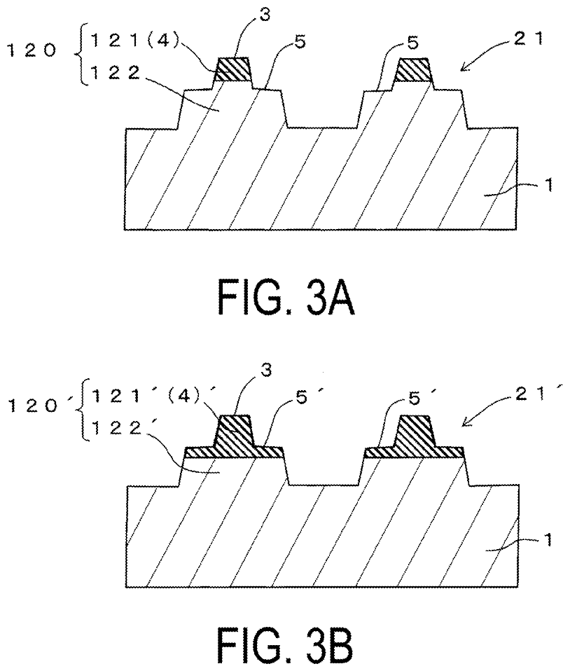

As illustrated in FIGS. 3A and 3B, protrusions 120 and 120′ may have stepped portions 5 and 5′ around support portions 122 and 122′, respectively. This increases the rigidity of the protrusions 120 and 120′. In the protrusion 120 illustrated in FIG. 3A, the stepped portion 5 is formed around the support portion 122, and a placement portion 121 is formed above the stepped surface. In the protrusion 120′ illustrated in FIG. 3B, a placement portion 121′ is formed by covering a stepped surface of the stepped portion 5′. The film 4 of the placement portion 121′ can suppress shedding that may occur from the stepped surface of the support portion 122′.

The stepped surface illustrated in FIGS. 3A and 3B has an annular shape but may have a square or rectangular frame shape.

The upper surface of the film 4 covering the stepped surface of the stepped portion 5 or the stepped surface of the stepped portion 5′ is larger than the placement surface 3 in mean value of cutting level differences (Rδc) each representing a difference between a cutting level at a load length rate of 25% in a roughness curve and a cutting level at a load length rate of 75% in the roughness curve. Due to this, even if a reaction product generated by the plasma treatment on the to-be-treated object floats, the possibility that this reaction product adheres to the upper surface of the film 4 covering the stepped surface of the stepped portion 5 or the stepped surface of the stepped portion 5′ and floats again is reduced. Since the placement surface 3 has less unevenness, the back surface of the to-be-treated object is less likely to be scratched.

Specifically, the difference between the mean values of the cutting level differences (Rδc) between the stepped surface and the placement surface 3 is preferably equal to or greater than 0.38 μm.

Here, the mean value of the cutting level differences (Rδc) of the stepped surface is equal to or less than 1.4 μm. This makes it difficult for a large particle to shed from the stepped surface, and the possibility that this particle adheres to the to-be-treated object is reduced. Note that the method for measuring the cutting level difference (Rδc) is the same as described above.

The stepped surface of the stepped portion 5 or 5′ has a larger mean value of the root mean square slopes (RΔq) in the roughness curve than that of the placement surface 3. Due to this, even if a reaction product generated by the plasma treatment on the to-be-treated object floats, the possibility that this reaction product adheres to the stepped surface and floats again is reduced. Since the placement surface 3 has less unevenness, the back surface of the to-be-treated object is less likely to be scratched.

Specifically, the difference between the mean values of the root mean square slopes (RΔq) of the stepped surface and the placement surface 3 is preferably equal to or greater than 0.34. The mean value of the root mean square slopes (RΔq) of the stepped surface is equal to or less than 1.1. This makes it difficult for a large particle to shed from the stepped surface, and the possibility that this particle adheres to the to-be-treated object is reduced.

Note that the method for measuring the root mean square slope (RΔq) is the same as described above.

The mean value of skewnesses (RSK1) in the roughness curve of the placement surface 3 may be smaller than the mean value of skewnesses (RSK2) in the roughness curve of the stepped surface or the upper surface (hereinafter, these are collectively referred to as stepped surface) of the films 4 or 4′ covering the stepped surface.

The skewness (RSK) in the roughness curve is defined in JIS B0601:2001 and is an index indicating a ratio between a peak part and a bottom part when a mean height in the roughness curve is a center line.

When the mean value of the skewnesses (RSK1) is smaller than the mean value of the skewnesses (RSK2), the planeness of the peak part on the placement surface 3 becomes higher than the planeness of the peak part on the stepped surface, and thus the aggressiveness of the placement surface on the to-be-treated object is suppressed. On the other hand, since the steepness of the peak part on the stepped surface becomes higher than the steepness of the peak part on the placement surface, when particles adhere to the stepped surface, a high supplementary effect is obtained, and the possibility that the particles float again is reduced even if a disturbance such as vibration is applied.

Specifically, the difference between the mean value of the skewnesses (RSK1) and the mean value of the skewnesses (RSK2) is preferably 0.2 or more, and in particular equal to or greater than 0.3.

The mean value of the skewnesses (RSK2) is equal to or less than 1.5. When the mean value of the skewnesses (RSK2) is in this range, it is difficult for the particles to shed from the peak part of the placement surface 3, and floating of the shed particles and adhering of the particles to the body to be adsorbed can be reduced.

The skewness (RSK1 and RSK2) can be measured using a laser microscope (VK-X1100 or its successor model manufactured by Keyence Corporation) in accordance with JIS B0601:2001. The measurement conditions and the calculation of the mean value are as described above.

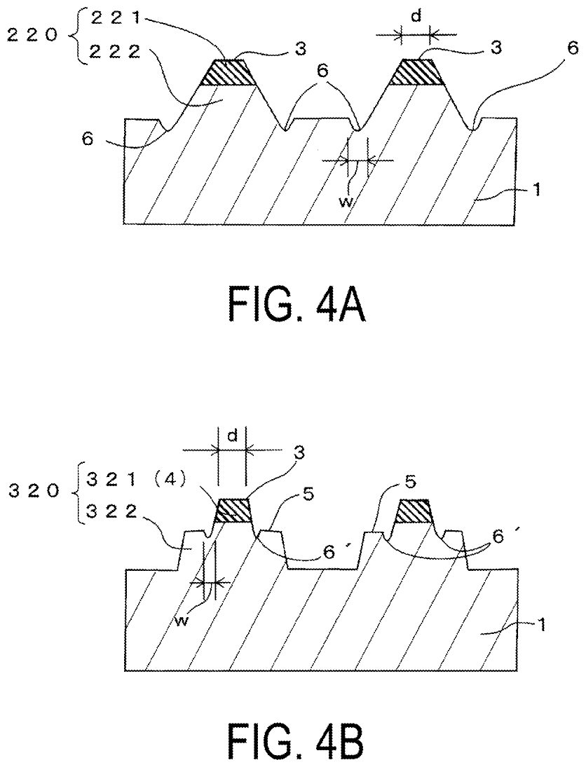

In the present disclosure, as in a protrusion 220 illustrated in FIG. 4A, a recess 6 having an annular shape extending in the depth direction from the surface of the substrate 1 is provided around a support portion 222, and a width w in the radial direction of the recess 6 is narrower than an equivalent circle diameter d of the placement surface 3 of a placement portion 221. Alternatively, as in a protrusion 320 illustrated in FIG. 4B, a recess 6′ having an annular shape extending in the depth direction from the stepped surface is provided, and the width w in the radial direction of the recess 6′ is narrower than the equivalent circle diameter d of the placement surface 3 of a placement portion 321 in the same and/or similar manner as described above. When the recess 6 is provided around the support portion 222 or on the stepped surface as described above, the reaction product can be easily captured by the recesses 6 or 6′, and the captured reaction product can be suppressed from floating again. Note that FIG. 4B illustrates the recess 6′ having the annular shape extending in the depth direction from the inner peripheral portion of the stepped surface, but the recess 6′ may extend in the depth direction from the outer peripheral portion of the stepped surface or may extend in the depth direction from a part including both the inner peripheral portion and the outer peripheral portion of the stepped surface. The inner peripheral portion of the stepped surface refers to a range of ½ of the width of the stepped surface starting with the inner periphery of the stepped surface as a starting point, and the outer peripheral portion of the stepped surface refers to a range excluding the inner peripheral portion of the stepped surface.

The recess 6 has an annular shape surrounding the protrusion 220, and the recess 6′ has an annular shape surrounding a portion above the stepped surface including the placement portion 321. The recess 6 and the recess 6′ have a circular outer periphery in top view but may have a polygonal shape including a triangular shape. The width w in the radial direction of each of the recesses 6 and 6′ is equal to or greater than 5% and equal to or less than 35% of the equivalent circle diameter d of the placement surface 3.

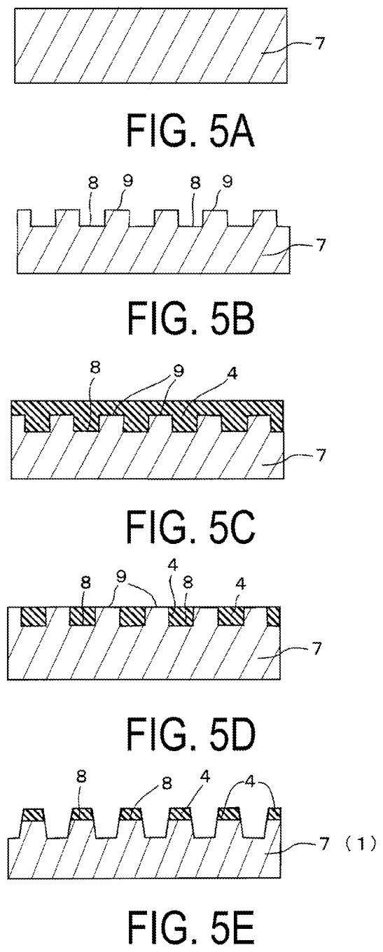

A method for producing the adsorption member of the present disclosure will be described with reference to FIGS. 5A to 5E. In producing the adsorption member of the present disclosure, first, a ceramic 7 containing silicon carbide as a main component is prepared (FIG. 5A).

That is, pure water, a dispersing agent, and a sintering aid such as a boron carbide powder or a phenol resin are added to the silicon carbide powder, and then the mixture is wet-mixed using a ball mill to prepare a slurry. Here, the content of the boron carbide powder with respect to 100 mass % of the silicon carbide powder is, for example, equal to or greater than 1 mass % and equal to or less than 3 mass %.

Next, an organic binder is added to and mixed with the slurry, and then the mixture is granulated by spray drying to obtain granules. Next, the granules are molded using various molding methods (e.g., cold isostatic pressing (CIP) or the like) to prepare a powder compact, and then this powder compact is cut to prepare a powder compact having a desired shape.

Next, if necessary, the temperature of this powder compact is increased in a nitrogen atmosphere for 10 to 40 hours, held at 450 to 650° C. for 2 to 10 hours, and then naturally cooled to degrease. Then, the ceramic 7 is produced by firing the degreased powder compact at equal to or greater than 1800° C. and equal to or less than 2000° C. in a reduced-pressure atmosphere of an inert gas such as an argon gas, for example.

Next, as illustrated in FIG. 5B, the laser machining process or the like using, for example, a carbon dioxide gas laser, a YAG laser, an ArF excimer laser, a KrF excimer laser, an XeCl excimer laser, or the like is applied on a surface to become the surface of the substrate to form recessed portions 8 and protruding portions 9, which are the remaining portion of the recessed portions 8. Next, as illustrated in FIG. 5C, the film 4 containing at least one type selected from the group consisting of silicon carbide, DLC, amorphous silicon, molybdenum, chromium, and tantalum as a main component covers the recessed portion 8 and the protruding portion 9.

The film 4 can be formed by, for example, chemical vapor deposition (CVD), physical vapor deposition (PVD), plating, vaporizing, plasma ion implantation method, ion plating method, thermal spraying, or the like. Among them, it is preferable to employ the chemical vapor deposition, and since the placement portion 21, 121, 221, or 321 to be formed is extremely compact and has almost no fine unevenness on the surface, particles generated from the adsorption member 10 can be extremely reduced.

On the other hand, warpage is likely to occur due to internal stress generated by a thermal expansion difference between the ceramic 7 and the film 4 during film formation by the chemical vapor deposition or the like. Therefore, as illustrated in FIG. 5D, the film 4 is split by applying grinding and/or polishing on the film 4 until the upper surface of the protruding portion 9 is exposed. This reduces the internal stress accumulated in the placement portion and reduces the flatness of the placement surface 3.

Next, as illustrated in FIG. 5E, the protruding portions 9 are removed by laser machining process, blast process, milling process, or the like, whereby the adsorption member 10 including the substrate 1 and the protrusion 2, 120, or 121 having a frustum shape can be obtained.

In order to provide the stepped portion 5 or 5′ around the support portion 122 as illustrated in FIG. 3A or 3B or to provide the recess 6 or 6′ having an annular shape around the support portion 222 or 322 as illustrated in FIG. 4A or 4B, respectively, the stepped portion 5 or 5′ and/or the recess 6 or 6′ may be formed simultaneously when the protruding portion 9 is removed by laser machining process, blast process, milling process, or the like.

The adsorption member of the present disclosure is suitably used for holding a to-be-treated object in a processing apparatus such as an exposure apparatus that processes a silicon wafer used for producing a semiconductor integrated circuit or a to-be-treated object such as a glass substrate used for producing a liquid crystal display apparatus, or an inspection apparatus for inspecting a silicon wafer, a glass substrate, or the like.

The embodiment of the present disclosure has been described above, but the present disclosure is not limited thereto, and various changes and improvements can be made within the range set forth in the present disclosure. For example, the adsorption member 10 is not limited to have a configuration using the vacuum chuck and may use an electrostatic chuck that electrostatically adsorbs the to-be-treated object.

### REFERENCE SIGNS

1 Substrate
2, 120, 120′, 220, 320 Protrusion
3 Placement surface
4, 4′ Film
5, 5′ Stepped portion
6, 6′ Recess
7 Ceramic
8 Recessed portion
9 Protruding portion
10 Adsorption member
21, 121, 121′, 221, 321 Placement portion
22, 122, 122′, 222, 322 Support portion

1. An adsorption member comprising:
a substrate made of ceramic containing silicon carbide as a main component; and
a plurality of protrusions formed on a surface of the substrate,
wherein each of the plurality of protrusions comprises a placement portion having a placement surface for placing a to-be-treated object and a support portion supporting the placement portion,
wherein the placement portion comprises a film containing at least one type selected from the group consisting of silicon carbide, diamond-like carbon, amorphous silicon, molybdenum, chromium, and tantalum as a main component, and
wherein a plurality of the films are independent of one another for each of the plurality of protrusion.

2. The adsorption member according to claim 1,
wherein the film extends toward an outer peripheral surface of the support portion and covers at least a part of the outer peripheral surface of the support portion.

3. The adsorption member according to claim 1,
wherein the surface of the substrate is larger than the placement surface in mean value of cutting level differences (Rδc) each representing a difference between a cutting level at a load length rate of 25% in a roughness curve and a cutting level at a load length rate of 75% in the roughness curve.

4. The adsorption member according to claim 3,
wherein the mean value of the cutting level differences (Rδc) of the surface of the substrate is equal to or less than 1.4 μm.

5. The adsorption member according to claim 3,
wherein a difference between a mean value of the cutting level differences (Rδc) of the surface of the substrate and a mean value of the cutting level differences (Rδc) of the placement surface is equal to or greater than 0.38 μm.

6. The adsorption member according to claim 1,
wherein the surface of the substrate is larger than the placement surface in a mean value of root mean square slopes (RΔq) in a roughness curve.

7. The adsorption member according to claim 6,
wherein the mean value of the root mean square slopes (RΔq) of the surface of the substrate is equal to or less than 1.1.

8. The adsorption member according to claim 6,
wherein a difference between mean values of the root mean square slopes (RΔq) is equal to or greater than 0.34.

9. The adsorption member according to claim 1,
wherein the protrusion comprises a stepped portion having a stepped surface around the support portion.

10. The adsorption member according to claim 9,
wherein the film covers the stepped surface of the stepped portion.

11. The adsorption member according to claim 9,
wherein the stepped surface or an upper surface of the film covering the stepped surface is larger than the placement surface in a mean value of cutting level differences (Rδc) each representing a difference between a cutting level at a load length rate of 25% in a roughness curve and a cutting level at a load length rate of 75% in the roughness curve.

12. The adsorption member according to claim 11,
wherein the mean value of the cutting level differences (Rδc) of the stepped surface or the upper surface of the film covering the stepped surface is equal to or less than 1.4 μm.

13. The adsorption member according to claim 11,
wherein a difference between mean values of the cutting level differences (Rδc) is equal to or greater than 0.38 μm.

14. The adsorption member according to claim 10,
wherein the stepped surface or an upper surface of the film covering the stepped surface is larger than the placement surface in a mean value of root mean square slopes (RΔq) in a roughness curve.

15. The adsorption member according to claim 14,
wherein the mean value of the root mean square slopes (RΔq) of the stepped surface or the upper surface of the film covering the stepped surface is equal to or less than 1.1.

16. The adsorption member according to claim 14,
wherein a difference between mean values of the root mean square slopes (RΔq) is equal to or greater than 0.34.

17. The adsorption member according to claim 1, comprising
a recess having an annular shape extending in a depth direction from the surface of the substrate and being provided around the support portion,
wherein a radial width of the recess is narrower than an equivalent circle diameter of the placement surface.

18. The adsorption member according to claim 9, comprising
a recess having an annular shape extending in a depth direction from the stepped surface,
wherein a radial width of the recess is narrower than an equivalent circle diameter of the placement surface.

19. A method for producing the adsorption member according to claim 1, comprising
processes performed in a following order:
(1) forming, on one surface of a substrate made of ceramic containing silicon carbide as a main component, a recessed portion and a protruding portion that is a remaining portion of the recessed portion,
(2) covering the recessed portion and the protruding portion with a film containing at least one type selected from the group consisting of silicon carbide, diamond-like carbon, amorphous silicon, molybdenum, chromium, and tantalum as a main component,
(3) splitting the film by applying the film with grinding and/or polishing until an upper surface of the protruding portion is exposed, and
(4) obtaining an adsorption member comprising the substrate and the frustum-shaped protrusion by removing the protruding portion.

20. An apparatus comprising the adsorption member according to claim 1.

21. (canceled)
